(19) United States
(12) Patent Application Publication
(10) Pub. No.: US 2022/0037489 A1
(43) Pub. Date: Feb. 3, 2022

(54) SEMICONDUCTOR STRUCTURE AND FORMING METHOD THEREOF

(71) Applicant: CHANGXIN MEMORY TECHNOLOGIES, INC., Hefei City (CN)

(72) Inventors: CHEONG SOO KIM, Hefei (CN); YONG GUN KIM, Hefei (CN); Xianrui HU, Hefei (CN); GuangSu SHAO, Hefei (CN)

(21) Appl. No.: 17/404,271

(22) Filed: Aug. 17, 2021

Related U.S. Application Data
(63) Continuation of application No. PCT/CN2021/094439, filed on May 18, 2021.

(30) Foreign Application Priority Data
Jul. 29, 2020 (CN) 202010744693.0

(51) Int. Cl. H01L 29/423; H01L 29/06

(52) U.S. Cl. CPC H01L 29/42368; H01L 29/0607

(57) ABSTRACT

A semiconductor structure and a forming method thereof are provided. The forming method includes: providing a semiconductor substrate including a source region and a drain region spaced apart; and forming a gate oxide layer, an interface layer and a gate layer on one side of the semiconductor substrate. The gate oxide layer, the interface layer and the gate layer are all disposed between the source region and the drain region. The interface layer is disposed on one side of the gate oxide layer facing away from the semiconductor substrate. The gate layer is disposed on one side of the interface layer facing away from the gate oxide layer. The area of orthographic projection of the interface layer on the semiconductor substrate is smaller than the area of orthographic projection of the gate oxide layer on the semiconductor substrate.

### CROSS-REFERENCE TO RELATED APPLICATION

The present application is a continuation application of International Patent Application No. PCT/CN2021/094439, filed on May 18, 2021, which claims priority to Chinese patent application No. 202010744693.0, filed on Jul. 29, 2020, and entitled “Semiconductor Structure and Forming Method thereof”. The disclosures of International Patent Application No. PCT/CN2021/094439 and Chinese patent application No. 202010744693.0 are hereby incorporated by reference in their entireties.

### TECHNICAL FIELD

The present disclosure relates to the technical field of semiconductors, and in particular to a semiconductor structure and a forming method thereof.

### BACKGROUND

With the development of a semiconductor technology, the size of a transistor is continuously decreased, and the thickness of a gate oxide layer also gets smaller. When a device is in an off state (taking an N-type semiconductor structure as an example, a gate voltage VG is less than 0 V), a Gate-Induced Drain Leakage (GIDL) current caused by band-to-band tunneling gets larger, which results in the reduction of device reliability and the increase of standby power consumption.

It should be noted that the information disclosed in the BACKGROUND part is only used to enhance an understanding of the background of the present disclosure, and thus may include information that does not constitute prior art known to those of ordinary skill in the art.

### SUMMARY

The present disclosure relates to the technical field of semiconductors, and in particular to a semiconductor structure and a forming method thereof, to overcome, to at least some extent, one or more problems due to limitations and defects of the related art.

According to an aspect of the present disclosure, a forming method of a semiconductor structure is provided, which may include operations as follows.

A semiconductor substrate including a source region and a drain region spaced apart is provided.

A gate oxide layer, an interface layer and a gate layer is formed on one side of the semiconductor substrate. The gate oxide layer, the interface layer and the gate layer are all disposed between the source region and the drain region, the interface layer is disposed on one side of the gate oxide layer facing away from the semiconductor substrate, the gate layer is disposed on one side of the interface layer facing away from the gate oxide layer, and the area of orthographic projection of the interface layer on the semiconductor substrate is smaller than the area of orthographic projection of the gate oxide layer on the semiconductor substrate.

According to an aspect of the present disclosure, a semiconductor structure is provided, which is manufactured by the forming method of the semiconductor structure described above.

It will be appreciated that the above general descriptions and detailed descriptions below are only exemplary and explanatory and not intended to limit the present disclosure.

### BRIEF DESCRIPTION OF THE DRAWINGS

The accompanying drawings, which are incorporated in and constitute a part of this specification, illustrate embodiments consistent with the present disclosure and, together with the specification, serve to explain the principles of the present disclosure. It is apparent to those of ordinary skill in the art that the drawings in the following description only illustrate some embodiments of the present disclosure, and other drawings may be obtained by those of ordinary skill in the art from these drawings without any creative effort.

FIG. 1 is a schematic structural diagram of a semiconductor structure in the related art.

FIG. 2 is a flowchart of a forming method of a semiconductor structure according to an embodiment of the present disclosure.

FIG. 3 is a schematic structural diagram of a semiconductor structure according to an embodiment of the present disclosure.

FIG. 4 is a schematic diagram of a semiconductor structure in which only a drain epitaxial region is disposed according to an embodiment of the present disclosure.

FIG. 5 is a schematic diagram of a semiconductor structure in which both a drain epitaxial region and a source epitaxial region are disposed according to an embodiment of the present disclosure.

FIG. 6 is a flowchart corresponding to operation S120 in FIG. 2.

FIG. 7 is a schematic diagram of a structure obtained after operation S1210 in a first embodiment of the present disclosure.

FIG. 8 is a schematic diagram of a structure obtained after operation S1210 in a second embodiment of the present disclosure.

FIG. 9 is a schematic diagram of a structure obtained after operation S1220 in a first embodiment of the present operation.

FIG. 10 is a schematic diagram of a structure obtained after operation S1220 in a second embodiment of the present disclosure.

FIG. 11 is a flowchart corresponding to operation S1220 in FIG. 4.

FIG. 12 is a schematic diagram of a structure obtained after operation S1230 in a first embodiment of the present disclosure.

FIG. 13 is a schematic diagram of a structure obtained after operation S1230 in a second embodiment of the present operation.

In the drawings: 100 semiconductor substrate; 101 drain region; 110 gate oxide layer; 120 gate layer; 1 semiconductor substrate; 11 source region; 12 drain region; 13 source epitaxial region; 14 drain epitaxial region; 2 gate oxide layer; 3 interface layer; 4 gate layer; 41 first dielectric layer; 42 gate electrode layer; 43 second dielectric layer; 5 barrier layer; 6 isolation layer; 61 first isolation layer; 62 second isolation layer; 63 third isolation layer.

### DETAILED DESCRIPTION

Exemplary embodiments will now be described more fully with reference to the accompanying drawings. However, the exemplary embodiments can be implemented in a variety of forms and should not be construed as limited to the embodiments set forth herein. Rather, these embodiments are provided to make the present disclosure thorough and complete, and the concepts of the example embodiments are fully communicated to those skilled in the art. The same reference numerals in the drawings indicate the same or similar structures, and thus the detailed descriptions thereof are omitted.

Although relative terms, such as “on” and “under”, are used in this specification to describe a relative relationship between one component and another component represented in the drawings, these terms are used in this specification only for convenience, for example, according to the directions of the examples described in the drawings. It will be appreciated that if a device illustrated in the drawings is flipped upside down, a component described as being “on” another component becomes a component described as being “under” the another component. When a structure is described as being “on” another structure, it may mean that the structure is integrally formed on the another structure, or the structure is “directly” disposed on the another structure, or the structure is “indirectly” disposed on the another structure through a structure.

The terms “one”, “a/an”, “the”, and “said” are used to indicate one or more elements/components/etc. The terms “including” and “having” are open-type inclusive and mean that there may be additional elements/components/etc. in addition to the listed elements/components/etc. The terms “first” and “second” are used merely as labels and are not intended to limit the number of objects.

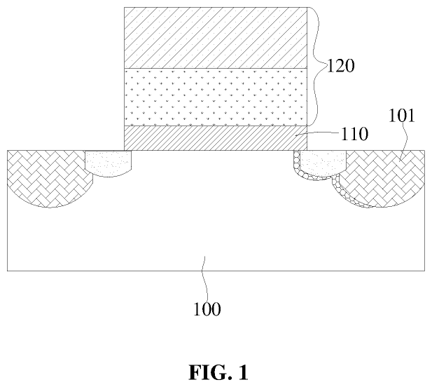

In the related art, as shown in FIG. 1, the semiconductor structure includes a semiconductor substrate 100, and a gate oxide layer 110 and a gate layer 120 formed on a surface of the semiconductor substrate 100. When a gate is in an off state (taking an N-type semiconductor structure as an example, a gate voltage VG is less than 0 V), band-to-band tunneling occurs in conduction band electrons and valence band holes since an energy band, near an interface, of an overlapping part where an impurity diffusion layer of a drain region 101 overlaps with the gate layer 120 is strongly curved, and a drain leakage current is formed, which results in that the performance of a semiconductor device is degraded, and the reliability is reduced. When the semiconductor structure is provided with a thin gate, a GIDL effect may cause the holes to damage the gate oxide layer or be captured by the thin gate through the tunneling effect, which results in that the performance of the semiconductor device is further degraded, and the reliability is further reduced.

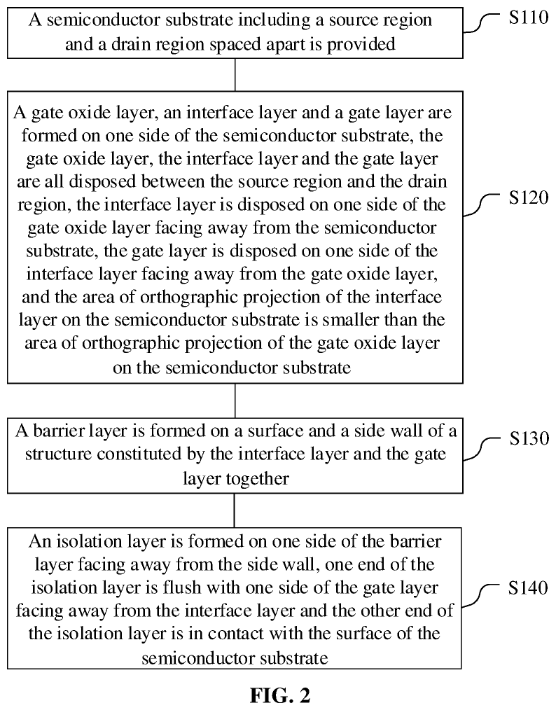

The embodiments of the present disclosure provide a forming method of a semiconductor structure. As shown in FIG. 2, the forming method may include the following operations S110 and S120.

In S110, a semiconductor substrate is provided. The semiconductor substrate includes a source region and a drain region spaced apart.

In S120, a gate oxide layer, an interface layer and a gate layer are formed on one side of the semiconductor substrate. The gate oxide layer, the interface layer and the gate layer are all disposed between the source region and the drain region. The interface layer is disposed on one side of the gate oxide layer facing away from the semiconductor substrate. The gate layer is disposed on one side of the interface layer facing away from the gate oxide layer. The area of orthographic projection of the interface layer on the semiconductor substrate is smaller than the area of orthographic projection of the gate oxide layer on the semiconductor substrate.

According to the forming method of the semiconductor structure, since the interface layer is disposed between the gate oxide layer and the gate layer, a physical size between the gate layer and the drain region is increased, and an electric field between a drain and a gate is reduced, so that a drain leakage current is reduced. Therefore, the standby power consumption can be effectively reduced, and the device reliability can be improved. Also, breakdown of the gate oxide layer is effectively avoided due to the increase of the size.

The operations of the forming method according to the embodiment of the present disclosure are described in detail below.

As shown in FIG. 2, in S110, a semiconductor substrate is provided. The semiconductor substrate includes a source region and a drain region spaced apart.

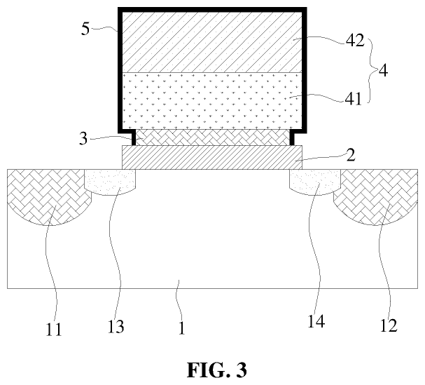

The material of the semiconductor substrate may be but not limited to silicon, and may also be other materials, which is not limited thereto. As shown in FIG. 3, the semiconductor substrate 1 may be a P-type substrate, and may include a source region 11 and a drain region 12 spaced apart. The source region 11 and the drain region 12 may be doped to form a source and a drain. For example, the source region 11 and the drain region 12 may be n-type doped to form a p-n junction. For example, the source region 11 and the drain region 12 may be doped with an n-type doping material, so that the source region 11 and the drain region 12 form an n-type semiconductor. The n-type doping material may be an element located in Group IV in the Periodic Table of the Elements, for example, phosphorus, but may also be materials of other elements, which is not enumerated here anymore.

In an embodiment, the source region 11 and the drain region 12 may be implanted with phosphorus ions by ion implantation. In practice, other processes may be adopted to dope the source region 11 and/or the drain region 12, which is not limited herein.

It should be noted that there may be a channel region between the source region 11 and the drain region 12. A current may flow in the channel region, and the current in the channel region may be controlled by a potential of the gate layer 4 to achieve a gate control function.

As shown in FIG. 2, in S120, a gate oxide layer, an interface layer and a gate layer are formed on one side of the semiconductor substrate. The gate oxide layer, the interface layer and the gate layer are all arranged between the source region and the drain region. The interface layer is arranged on one side of the gate oxide layer facing away from the semiconductor substrate. The gate layer is arranged on one side of the interface layer facing away from the gate oxide layer. The area of orthographic projection of the interface layer on the semiconductor substrate is smaller than the area of orthographic projection of the gate oxide layer on the semiconductor substrate.

As shown in FIG. 3, a gate oxide layer 2, an interface layer 3 and a gate layer 4, which are stacked, may be formed on one side of a semiconductor substrate 1, and the gate oxide layer 2, the interface layer 3 and the gate layer 4 are all arranged in a region between a source region 11 and a drain region 12. For example, the gate oxide layer 2, the interface layer 3 and the gate layer 4 are all arranged right above a channel region between the source region 11 and the drain region 12. By arranging the interface layer 3 between the gate oxide layer 2 and the gate layer 4, a physical size between the gate layer 4 and the drain region 12 is increased, and an electric field between the drain region 12 and the gate layer 4 is reduced, thereby reducing a drain leakage current. Therefore, the standby power consumption can be effectively reduced, and the device reliability can be improved. Also, the breakdown of the gate oxide layer 2 can be effectively avoided due to the increase of the size.

The gate oxide layer 2 is formed right above the channel region of the semiconductor substrate 1, and may be a thin film formed on the surface of the semiconductor substrate 1 or a coating layer formed on the surface of the semiconductor substrate 1, which is not limited herein.

The interface layer 3 is arranged on one side of the gate oxide layer 2 facing away from the semiconductor substrate 1, so that the physical size between the gate layer 4 and the drain region 12 can be increased, the electric field between the drain region 12 and the gate layer 4 is reduced, thereby reducing the drain leakage current. Therefore, the standby power consumption can be effectively reduced, and the device reliability can be improved. Also, the GIDL effect is reduced due to the arrangement of the interface layer 3, and the breakdown of the gate oxide layer 2 can be effectively avoided.

The gate layer 4 is arranged on one side of the interface layer 3 facing away from the gate oxide layer 2 and is used for controlling electric field intensity on a surface of a source or a drain, thereby controlling a current between the source and the drain. The gate layer 4 may be a thin film formed on the surface of the interface layer 3 facing away from the gate oxide layer 2, or may be a coating layer formed on the surface of the interface layer 3 facing away from the gate oxide layer 2, which is not limited herein.

In an embodiment, the gate layer 4 may include a first dielectric layer 41 and a gate electrode layer 42. The first dielectric layer 41 may be arranged between the gate electrode layer 42 and the interface layer 3, the material of the first dielectric layer 41 may be polysilicon or doped polysilicon, or the like, and the material of the gate electrode layer 42 may be metal tungsten.

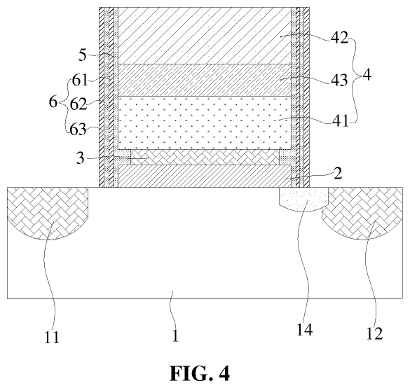

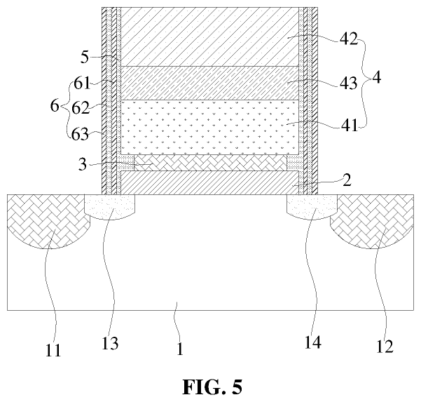

In an embodiment, as shown in FIG. 4 and FIG. 5, the gate layer 4 may further include a second dielectric layer 43. The second dielectric layer 43 may be arranged between the first dielectric layer 41 and the gate electrode layer 42 for preventing a metal material in the gate electrode layer 42 from diffusing towards the first dielectric layer 41. The material of the second dielectric layer 43 may be titanium nitride.

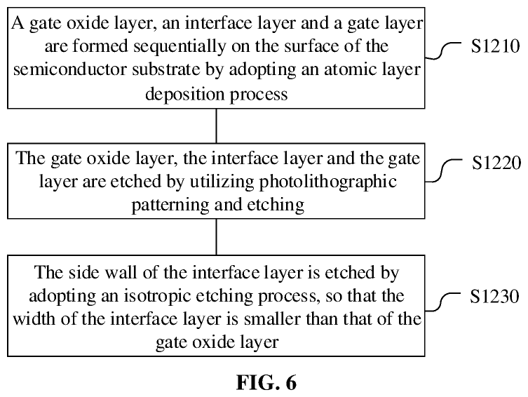

In an embodiment, as shown in FIG. 6, the operation that a gate oxide layer 2, an interface layer 3 and a gate layer 4 are formed on one side of the semiconductor substrate 1 may include operations S1210 to S1230. That is, operation S120 may include the following operations S1210 and S1230.

In S1210, a gate oxide layer, an interface layer and a gate layer are sequentially formed on the surface of the semiconductor substrate by adopting an atomic layer deposition process.

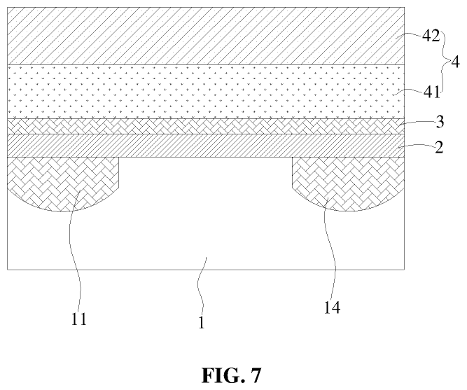

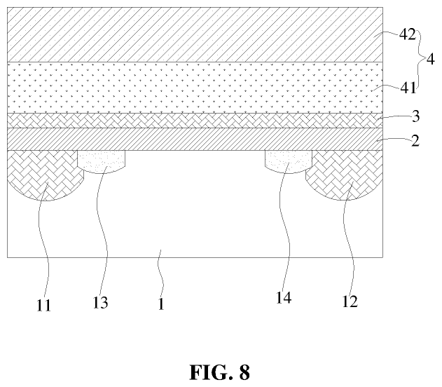

As shown in FIG. 7 and FIG. 8, the surface of the semiconductor substrate 1 may be provided with a source region 11, a channel region and a drain region 12 adjacently disposed. The gate oxide layer 2 may be formed on the surface of the semiconductor substrate 1 by means of chemical vapor deposition, thermal oxidation, physical vapor deposition, atomic layer deposition or the like. The gate oxide layer 2 may completely cover the source region 11, the channel region and the drain region 12 for process convenience. The gate oxide layer 2 may also be formed by other manner in practical, which is not limited herein.

The material of the gate oxide layer 2 may include silicon dioxide, a high-k dielectric material or other dielectric materials. The thickness of the gate oxide layer may range from 20 Å to 30 Å, for example, 20 Å, 22 Å, 24 Å, 26 Å, 28 Å, or 30 Å.

The interface layer 3 is formed on the surface of the gate oxide layer 2 facing away from the semiconductor substrate 1. The material of the interface layer may be silicon nitride or other high-k dielectrics. The thickness of the interface layer may range 50 Å to 100 Å, for example, 50 Å, 60 Å, 70 Å, 80 Å, 90 Å, or 100 Å.

In some embodiments, the interface layer 3 may be formed on the gate oxide layer 2 by a process such as chemical vapor deposition, physical vapor deposition, atomic layer deposition, spin coating, ink jet, screen printing, coating, or vacuum evaporation, which is not limited herein.

The gate layer 4 is formed on one side of the interface layer 3 facing away from the gate oxide layer 2. In some embodiments, the gate layer 4 may be formed by a process such as chemical vapor deposition, vacuum evaporation, or atomic layer deposition. When the gate layer 4 has a multilayer structure, layer-by-layer deposition may be performed, and a molding process corresponding to a material type of each layer may be selected according to the material type.

In an embodiment, the gate layer 4 may include a first dielectric layer 41, a second dielectric layer 43 and a gate electrode layer 42. The material of the first dielectric layer 41 may be polysilicon. The material of the second dielectric layer 43 may be titanium nitride. The material of the gate electrode layer 42 may be metal tungsten. The first dielectric layer 41 may be formed on the interface layer 3 by adopting an atomic layer deposition process. The second dielectric layer 43 may be formed on the first dielectric layer 41 by adopting a chemical vapor deposition process. The gate electrode layer 42 may be formed above the second dielectric layer 43 by vacuum evaporation. In some embodiments, the gate layer 4 may further include other layers, and the layers may be formed by adopting other processes, which is not limited herein.

In S1220, the gate oxide layer, the interface layer and the gate layer are etched by photolithographic patterning and etching.

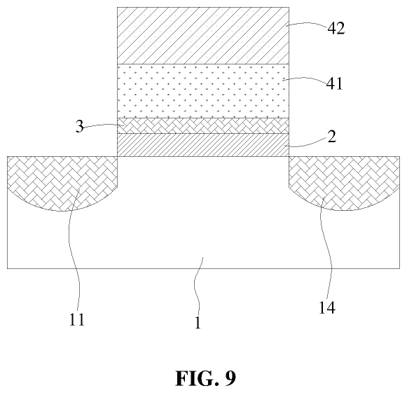

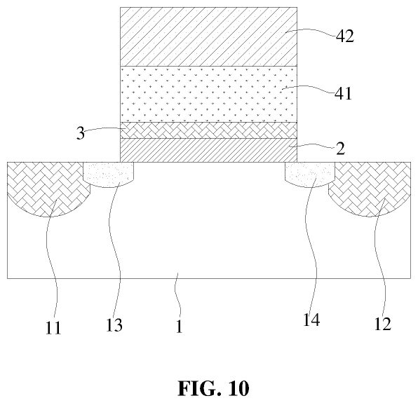

The gate oxide layer 2, the interface layer 3 and the gate layer 4 are etched by photolithographic patterning and etching to form a gate structure. That is, the gate structure includes a gate oxide layer 2, an interface layer 3 and a gate layer 4 right above the channel region between the source region 11 and the drain region 12. FIG. 9 and FIG. 10 show a structure obtained after operation S1220 of the forming method of the present disclosure.

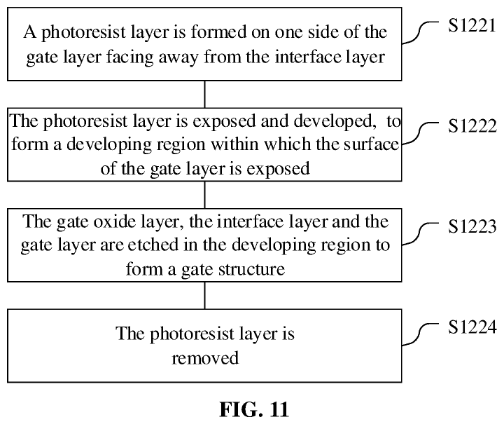

In an embodiment, as shown in FIG. 11, the operation S1220 of the gate oxide layer 2, the interface layer 3 and the gate layer 4 are etched by photolithographic patterning and etching may include the following operations S1221, S1222 and S1223.

In S1221, a photoresist layer is formed on one side of the gate layer facing away from the interface layer.

A photoresist layer may be formed on one side of the gate layer 4 facing away from the interface layer 3 by spin coating or other manners. The material of the photoresist layer may be a positive photoresist or a negative photoresist, which is not limited herein.

In S1222, the photoresist layer is exposed and developed, to form a developing region within which the surface of the gate layer is exposed.

The photoresist layer is exposed by a mask. A pattern of the mask is matched with patterns required by the gate oxide layer 2, the interface layer 3 and the gate layer 4. Subsequently, the exposed photoresist layer is developed to form a developing region, a pattern of which is the same as the patterns required by the gate oxide layer 2, the interface layer 3 and the gate layer 4.

In S1223, the gate oxide layer, the interface layer and the gate layer are etched in the developing region to form a gate structure.

The etching method may include processes such as dry etching, wet etching or plasma etching. It should be noted that the etching of the gate oxide layer 2, the interface layer 3 and the gate layer 4 may be implemented by performing photoetching process one time, and the gate oxide layer 2, the interface layer 3 and the gate layer 4 may be sequentially etched respectively. That is, only one layer is etched at a time. The gate oxide layer 2 is etched, the interface layer 3 is then etched, and the gate oxide layer 2 is finally etched.

In S1224, the photoresist layer is removed.

After the etching process is completed, the photoresist layer on the surface of the gate layer 4 may be removed by cleaning with a cleaning solution or by a process such as ashing.

In S1230, a side wall of the interface layer is etched by adopting an isotropic etching process so that the width of the interface layer is smaller than that of the gate oxide layer.

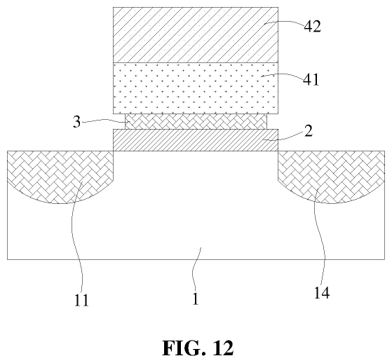

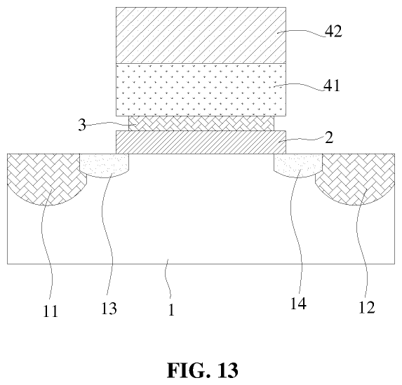

As shown in FIG. 12 and FIG. 13, a wet etching process may be used to perform isotropic etching on the side wall of the interface layer 3, so that the width of the interface layer 3 is smaller than that of the gate oxide layer 2 and also smaller than that of the gate layer 4. In some embodiments, selective wet etching is performed on the interface layer 3 by using phosphoric acid.

In an embodiment, the forming method of the semiconductor structure of the present disclosure may further include the following operation S130.

In S130, a barrier layer is formed on a surface and a side wall of a structure constituted by the interface layer and the gate layer together.

As shown in FIG. 3, a barrier layer 5 may be formed on the surface and the side wall of a structure constituted by the interface layer 3 and the gate layer 4 together by adopting a process such as atomic layer deposition, chemical vapor deposition, physical vapor deposition, magnetron sputtering or vacuum evaporation. The barrier layer 5 may be profile-attached to the surface and the side wall of the structure constituted by the interface layer 3 and the gate layer 4 together. The barrier layer 5 is made of a material with a small dielectric constant, which is beneficial to reduce the electric field intensity of a depletion layer and further reduce the GIDL effect.

In an embodiment, the material of the barrier layer 5 is silicon dioxide. The thickness of the barrier layer may range 30 Å to 50 Å, for example, 30 Å, 35 Å, 40 Å, 45 Å, or 50 Å.

In an embodiment, the forming method of the semiconductor structure of the present disclosure may further include the following operations S140.

In S140, an isolation layer is formed on one side of the barrier layer facing away from the side wall. One end of the isolation layer is flush with one side of the gate layer facing away from the interface layer, and the other end of the isolation layer is in contact with the surface of the semiconductor substrate.

As shown in FIG. 4 and FIG. 5, an isolation layer 6 may be disposed above the semiconductor substrate and may be disposed on one side of the barrier layer 5 facing away from the side wall. One end of the isolation layer may be flush with one side of the gate layer 4 facing away from the interface layer, and the other end of the isolation layer may be in contact with the surface of the semiconductor substrate. The source and/or the drain may be separated from a side face of the gate layer 4 by a non-zero distance through the barrier layer 5 and the isolation layer 6, so that the GIDL effect is reduced, and the standby power consumption is reduced. The isolation layer 6 may also cover a top surface of the structure constituted by the interface layer 3 and the gate layer 4, which is not limited herein.

In an embodiment, the isolation layer 6 may have a multilayer structure, and may include a first isolation layer 61, a second isolation layer 62 and a third isolation layer 63. The first isolation layer 61 may be adjacent to the barrier layer 5. The second isolation layer 62 may be located between the first isolation layer 61 and the third isolation layer 63. A material of the first isolation layer 61 may be silicon nitride, a material of the second isolation layer 62 may be silicon oxide, and a material of the third isolation layer 63 may be silicon nitride.

In an embodiment, the semiconductor substrate 1 further includes a drain epitaxial region 14. As shown in FIG. 4 and FIG. 5, the drain epitaxial region 14 is disposed between the source region 11 and the drain region 12 and is adjacent to the drain region 12. An end portion of the drain epitaxial region deviating from the drain region 12 may be adjacent to an end portion of the gate oxide layer 2 close to the drain region 12, which can reduce the channel electric field, and reduce a hot carrier effect.

In addition, a doping concentration of the drain epitaxial region 14 is smaller than that of the drain region 12. In an embodiment, the drain epitaxial region 14 and the drain region 12 have the same doping type. In an embodiment, a n-type doping material may be doped within the drain epitaxial region 14, to form the drain epitaxial region 14 into an n-type semiconductor. The n-type doping material may be an element located in Group IV in the Periodic Table of the Elements, for example, phosphorus.

The drain epitaxial region 14 may be implanted with phosphorus ions by ion implantation. In practical, other processes may be adopted to dope the drain epitaxial region 14, which is not limited herein. It should be noted that in a first embodiment of the present disclosure, as shown in FIG. 7, FIG. 9 and FIG. 12, the drain epitaxial region 14 may be doped by ion implantation after the gate oxide layer 2, the interface layer 3 and the gate layer 4 are formed. In a second embodiment of the present disclosure, as shown in FIG. 8, FIG. 10 and FIG. 13, the drain epitaxial region 14 may be doped before the gate oxide layer 2, the interface layer 3 and the gate layer 4 are formed, which is not limited herein.

In an embodiment, the semiconductor substrate 1 may further include a source epitaxial region 13. The source epitaxial region 13 is disposed between the source region 11 and the drain region 12 and may be adjacent to the source region 11. An end portion of the source epitaxial region deviating from the source region 11 may be adjacent to an end portion of the gate oxide layer 2 close to the source region 11, which can reduce the channel electric field, and reduce the hot carrier effect.

In addition, a doping concentration of the source epitaxial region 13 is smaller than that of the source region 11. In an embodiment, the source epitaxial region 13 and the source region 11 have the same doping type. In some embodiment, a n-type doping material may be doped within the source epitaxial region 13, to form the source epitaxial region 13 into an n-type semiconductor. The n-type doping material may be an element located in Group IV in the Periodic Table of the Elements, for example, phosphorus.

The source epitaxial region 13 may be implanted with phosphorus ions by ion implantation. In practical, other processes may be adopted to dope the source epitaxial region 13, which is not limited herein. It should be noted that the source epitaxial region 13 may be doped by ion implantation after the gate oxide layer 2, the interface layer 3 and the gate layer 4 are formed. The source epitaxial region 13 may also be doped before the gate oxide layer 2, the interface layer 3 and the gate layer 4 are formed, which is not limited herein.

It should be noted that during formation, both the source region 11 and the drain region 12 may be bilaterally doped, or any one of the source region 11 or the drain region 12 may be unilaterally doped, which is not limited herein.

The embodiments of the present disclosure further provide a semiconductor structure which is manufactured by the forming method of the semiconductor structure in any one of the embodiments described above. Referring to FIG. 3 to FIG. 5, a specific structure is shown. For the detailed structure and beneficial effects of the semiconductor structure, reference may be made to the forming method of the semiconductor structure of the embodiments described above, which are not described in detail herein anymore. For example, the semiconductor structure may be an N-type semiconductor structure or a P-type semiconductor structure, which is not limited herein.

After considering the specification and implementing the disclosure disclosed here, other implementation solutions of the present disclosure would readily be conceivable to those skilled in the art. The present disclosure is intended to cover any variations, usage, or adaptations of the present disclosure. These variations, usage, or adaptations conform to the general principles of the disclosure and include such departures from the present disclosure as come within known or customary practice in the art. The specification and embodiments are only regarded as exemplary, and the true scope and spirit of the present disclosure are indicated by the appended claims.

1. A forming method of a semiconductor structure, comprising:
providing a semiconductor substrate comprising a source region and a drain region spaced apart; and
forming a gate oxide layer, an interface layer and a gate layer on one side of the semiconductor substrate, wherein the gate oxide layer, the interface layer and the gate layer are all disposed between the source region and the drain region, the interface layer is disposed on one side of the gate oxide layer facing away from the semiconductor substrate, the gate layer is disposed on one side of the interface layer facing away from the gate oxide layer, and an area of orthographic projection of the interface layer on the semiconductor substrate is smaller than an area of orthographic projection of the gate oxide layer on the semiconductor substrate.

2. The forming method of claim 1, wherein a dielectric constant of the interface layer is greater than that of the gate oxide layer.

3. The forming method of claim 1, further comprising:
forming a barrier layer on a surface and a side wall of a structure constituted by the interface layer and the gate layer together.

4. The forming method of claim 1, wherein the forming the gate oxide layer, the interface layer and the gate layer on one side of the semiconductor substrate comprises:
sequentially forming a gate oxide layer, an interface layer and a gate layer on a surface of the semiconductor substrate by adopting an atomic layer deposition process;
etching the gate oxide layer, the interface layer and the gate layer by utilizing photolithographic patterning and etching; and
etching a side wall of the interface layer by adopting an isotropic etching process, to enable a width of the interface layer to be smaller than that of the gate oxide layer.

5. The forming method of claim 4, wherein the etching the gate oxide layer, the interface layer and the gate layer by utilizing photolithographic patterning and etching comprises:
forming a photoresist layer on one side of the gate layer facing away from the interface layer;
exposing and developing the photoresist layer, to form a developing region within which the surface of the gate layer is exposed;
etching the gate oxide layer, the interface layer and the gate layer in the developing region to form a gate structure; and
removing the photoresist layer.

6. The forming method of claim 3, further comprising:
forming an isolation layer on one side of the barrier layer facing away from the side wall, wherein one end of the isolation layer is flush with one side of the gate layer facing away from the interface layer, and the other end of the isolation layer is in contact with a surface of the semiconductor substrate.

7. The forming method of claim 1, wherein the gate layer comprises a first dielectric layer, a second dielectric layer and a gate electrode layer, the second dielectric layer is disposed between the first dielectric layer and the gate electrode layer, the first dielectric layer is disposed on a surface of the interface layer facing away from the gate oxide layer, and a material of the second dielectric layer is titanium nitride.

8. The forming method of claim 2, wherein the gate layer comprises a first dielectric layer, a second dielectric layer and a gate electrode layer, the second dielectric layer is disposed between the first dielectric layer and the gate electrode layer, the first dielectric layer is disposed on a surface of the interface layer facing away from the gate oxide layer, and a material of the second dielectric layer is titanium nitride.

9. The forming method of claim 3, wherein the gate layer comprises a first dielectric layer, a second dielectric layer and a gate electrode layer, the second dielectric layer is disposed between the first dielectric layer and the gate electrode layer, the first dielectric layer is disposed on a surface of the interface layer facing away from the gate oxide layer, and a material of the second dielectric layer is titanium nitride.

10. The forming method of claim 4, wherein the gate layer comprises a first dielectric layer, a second dielectric layer and a gate electrode layer, the second dielectric layer is disposed between the first dielectric layer and the gate electrode layer, the first dielectric layer is disposed on a surface of the interface layer facing away from the gate oxide layer, and a material of the second dielectric layer is titanium nitride.

11. The forming method of claim 5, wherein the gate layer comprises a first dielectric layer, a second dielectric layer and a gate electrode layer, the second dielectric layer is disposed between the first dielectric layer and the gate electrode layer, the first dielectric layer is disposed on a surface of the interface layer facing away from the gate oxide layer, and a material of the second dielectric layer is titanium nitride.

12. The forming method of claim 6, wherein the gate layer comprises a first dielectric layer, a second dielectric layer and a gate electrode layer, the second dielectric layer is disposed between the first dielectric layer and the gate electrode layer, the first dielectric layer is disposed on a surface of the interface layer facing away from the gate oxide layer, and a material of the second dielectric layer is titanium nitride.

13. The forming method of claim 7, wherein the semiconductor substrate further comprises:
a drain epitaxial region adjacent to the drain region, wherein other end of the drain epitaxial region is adjacent to an end portion of the gate oxide layer close to the drain region, and a doping concentration of the drain epitaxial region is smaller than that of the drain region.

14. The forming method of claim 13, wherein the semiconductor substrate further comprises:
a source epitaxial region, wherein one end of the source epitaxial region is adjacent to the source region, the other end of the source epitaxial region is adjacent to an end portion of the gate oxide layer close to the source region, and a doping concentration of the source epitaxial region is smaller than that of the source region.

15. A semiconductor structure, manufactured by the forming method of the semiconductor structure of any one of claim 1.
